(19) United States
(12) Patent Application Publication
(10) Pub. No.: US 2025/0384192 A1
(43) Pub. Date: Dec. 18, 2025

(54) COMPUTER-IMPLEMENTED METHOD AND COMPUTING DEVICE WITH A MODELING OF THE ABANDONMENT PROCESS OF OIL AND NATURAL GAS WELLS

(71) Applicants: PETRÓLEO BRASILEIRO S.A. – PETROBRAS, Rio de Janeiro (BR); UNIVERSIDADE FEDERAL FLUMINENSE - UFF, Rio de Janeiro (BR)

(72) Inventors: Luis Carlos MARQUES PIRES, Rio de Janeiro (BR); Saulo ALELUIA BARCELOS, Vitória (BR); Miguel Angelo SPIRITO JUNIOR, Niterói (BR); Camila Aparecida ABELHA ROCHA, Niterói (BR); Troner ASSENHEIMER DE SOUZA, Rio de Janeiro (BR); Victor Rolando RUIZ AHON, Niterói (BR); Jan YUZO KOHARA, Rio de Janeiro (BR); Marcelo Victor TOMAZ DE MATOS, Aracaju (BR); Lucas Henrique QUEIROZ DOS REIS, São Francisco (BR)

(21) Appl. No.: 19/196,206

(22) Filed: May 1, 2025

(30) Foreign Application Priority Data
Jun. 12, 2024 (BR) 1020240119142

(51) Int. Cl. G06F 30/28

(52) U.S. Cl. CPC G06F 30/28

(57) ABSTRACT

The present disclosure refers to a computer-implemented method and computing device with a modeling of the abandonment process of oil wells, being considered a computational tool for intelligent prediction of abandonment of oil wells. The method collects information from databases and performs a first analysis, thereby grouping generic data common to all alternatives, and which serves as an initial basis for evaluation.

### FIELD OF THE DISCLOSURE

The present disclosure pertains to the technical field of oil and natural gas, specifically related to modeling, simulation and evaluation of oil reservoirs, and refers to a computational tool or method implemented by computer with an optimized modeling of the abandonment process of oil and natural gas wells.

### BACKGROUNDS OF THE DISCLOSURE

After the life cycle of an oil and natural gas well has ended, it is necessary to reestablish conditions of isolation of aquifers and intervals with flow potential that resemble those originally found, before drilling, in order to prevent the inadmissible flow of fluids between permeable formations, either inside the well or through the annular spaces, and/or flow of fluids to the seabed or surface.

This isolation is achieved by establishing Integrated Barrier Sets-IBSs, which are a set of one or more elements positioned to prevent any unwanted flow. For the permanent abandonment of oil wells, permanent IBSs are considered, which must be positioned in an impermeable formation, and which is competent at the base of the IBS. The most common element for this isolation is cement, but other materials with similar performance can be used.

Even though there are wells with different features, such as completed cased or uncased intervals, presence of liner-type casings, absence or plurality of zones with flow potential/aquifers, built in terrestrial or maritime environments, with very shallow (up to 100 m) or deep water depths, they will nevertheless have similar operational abandonment features.

Depending on this construction arrangement, the operations may or may not require the removal of the production string—PS or injection string—IS from inside the well and may or may not require the assistance of safety valves (BOP—Blowout Preventer) for control and safety, always complying with the requirement to operate with 2 IBSs.

However, there are several specific cases that allow/require different approaches during abandonment, both in terms of technique and sequence of operations, such as: well deviation; horizontal or highly inclined wells; multilateral wells; shallow over-pressurized intervals and investigation wells; biogenic-nature hydrocarbons; fluid discharge; creeping formations; casing cutting; casing destruction (Section milling); PWC (Perforate, Wash and Cement); through-tubing abandonment; through-tubing abandonment in sections with cables and control/chemical injection lines; permanent abandonment with removal of the production/injection string in the open sea; riserless-type interventions, which do not require the use of a riser in the operation; trapping of radioactive sources in the well; and unplanned abandonment operations.

Due to the complexity of the process and the specificity of each hydrocarbon field and reservoir, there are different methodologies that can be used in the abandonment of wells, taking into account technical-economic efficiency, through the ALARP risk approach—(As Low As Reasonably Practicable).

Since this is a multidisciplinary decision-making process, in order to evaluate the best strategies for the operation, and due to the volume of data involved and the inherent difficulties of the process, there is a need to optimize and measure the performance of these decisions, with a view to predicting future operations for wells/fields with similar features and greater efficiency in the abandonment of wells and/or groups of wells (clusters).

Currently, there is no known computational tool or method capable of presenting all the abandonment options available for oil and natural gas wells based on the best abandonment techniques and history, taking into account the available technologies, equipment availability and known techniques, thus supporting the decision-making process for selecting the effective scope of abandonment.

In this way, given the limitations and the technical problem reported above, the present disclosure presents a computer-implemented method with a modeling of the abandonment process of oil and natural gas wells, being considered a computational method for intelligent and optimized prediction of abandonment of oil and natural gas wells.

The method allows integration into a computer system that enables the execution of various types of well abandonment projects, and in parallel, makes it possible to optimize the abandonment plan, reducing the duration of operations through the application of new technologies and early indication of wells that will require derogation with the Agência Nacional de Petróleo—ANP (Brazilian Oil Agency).

### STATE OF THE ART

Documents describing methods similar to the present disclosure have been identified. However, it is important to emphasize that there are technical features that differ considerably, as we will see below.

Document BR1120160033213 is part of the general state of the art and describes a well abandonment method, well abandonment system, well abandonment generation system and tangible computer-readable medium. The presented disclosure automates oil and natural gas well abandonment procedures and groups similar wells based on inspection data, generating, by extrapolation, an optimized abandonment sequence and a cost estimate.

The main difference between this said document and the present disclosure lies in idempotency, that is, the ability of an operation to be applied multiple times with the same result. This is due to the fact that the present disclosure performs an individual analysis of each well in the database, avoiding sampling and extrapolation. In the present disclosure, the wells are evaluated individually, testing all alternatives, with a ranking based on a known history of operations and the best technical choice. Unlike the aforementioned document, which groups wells and extrapolates an average solution, the present disclosure considers all possibilities and allows the user to choose between several tested options that have been validated.

Another significant difference concerns the independence of inspection data. The present disclosure is capable of evaluating wells at any stage of their productive life, not being limited to those indicated for abandonment and with corresponding reports, as is the case in this said document. This is because the tool evaluates wells based on all available structural data, even in the absence of reports indicating problems.

In addition, whereas the grouping made by the document is based on features of the sample space, the alternatives defined in the present disclosure are based on pre-established criteria. Common features are no those that form groups, but clear criteria that create alternatives, allowing the formation of groups with similar features after the evaluation of the wells.

Another notable distinction between this said document and the present disclosure lies in the level of detail found in the latter, which can be considered a significant technical difference. Whereas this said document uses information exclusively from inspection reports, which can be supplemented by other reports with human interference, the present disclosure goes further by delving into specific technical issues.

This includes analyzing the size of the interval available for the composition of a solid set of barriers, determining the number of possible barriers, suggesting the most suitable location for the composition, comparing alternatives and considering technological limitations. It is worth noting that the crucial difference is the ability of the present disclosure to perform these analyses autonomously, based on the data available in the databases. Additionally, the integration of the present disclosure with artificial intelligence (AI) stands out, transforming the entire process mentioned into a cycle of continuous learning and constant improvement.

In turn, the document by Almeida (2022), titled “Inteligência Artificial Aplicada Na Determinação Da Rota De Abandono Permanente De Poços” (“Artificial Intelligence Applied to the Determination of the Permanent Abandonment Route of Wells”) is also part of the general state of the art and presents a model with the same purpose as the present disclosure. However, it is noted that the model presented in this said document, as well as its groundings, despite having been indicated as capable of determining the permanent abandonment route of wells, is not capable of doing so because it is very superficial and generic. The aforementioned document presents a model with nine (9) variables responsible for categorizing the bank with the respective suggested abandonment groups, three (3) in total.

In summary, the artificial intelligence model presented in this said document can be understood as a presentation of a generic categorization model using a decision tree, in which nine (9) variables were assigned to different objects, with three (3) alternatives as a possible final result, and in which there was convergence of the analysis groups in relation to the training groups. The simple nomenclature linked to the abandonment of wells does not necessarily characterize a relation between the abandonment and the model proposed in the present disclosure.

The present disclosure, in addition to having a technical basis aligned with the industry's standards and good practices for the basic definition of each alternative, which are nine (9) in total and which are already at a more in-depth level of the three (3) groups mentioned in the aforementioned document, follows a careful analysis of all relevant information from the wells, which results in a system with hundreds of variables, compared to nine (9) of those attributed to the objects used in the model in the aforementioned document.

Document U.S. Pat. No. 10,430,725B2 protects a machine learning system for oil analysis with machine learning analysis applications for the oil and gas industry. It should be noted that the “PALM” system, described in this said document, focuses only on optimizing hydrocarbon production in oil wells. And based on economic and technical factors analyzed by this tool, the need to abandon the well is indicated.

In contrast, the present disclosure analyzes all the features related to the well to determine the best abandonment route, considering the particularities of each alternative. This approach allows evaluating wells at any stage of their productive life, including before the tool presented in this said document t indicates the need for abandonment.

Finally, document BR1120170255553, which is also part of the general state of the art, describes a system and method for real-time monitoring and estimation of production performance of an intelligent well system. In contrast, the present disclosure focuses on the optimized modeling of the well abandonment process. Even if this said document indicated the abandonment of a specific well, it would not provide additional related information, unlike the present disclosure, where the focus is the abandonment itself and all operations associated with the same.

In this way, considering the disclosure above, it is possible to perceive relevant differences between the solutions presented in the state of the art and the present disclosure, and it is further possible to verify the presence of a differential technical effect in the present disclosure, considering the intrinsic advantages of the implemented method.

### BRIEF DESCRIPTION OF THE DISCLOSURE

The present disclosure refers to a computer-implemented method with a modeling of the abandonment process of oil wells, being considered a computational tool for intelligent prediction of abandonment of oil wells. The method first collects information from the databases relating to the well structure and performs a first analysis, grouping generic data common to all well abandonment alternatives, which serves as an initial basis for evaluation. The grouping of scope alternatives into type groups, Through-Tubing, Conventional and Superconventional, is then explained. The set of data used is presented, as well as the possible points of attention and alerts for each of the abandonment alternatives. From these groups, a distinction is made between the subtypes, which will be part of the group of alternatives subject to selection: through-tubing with direct pumping of cement; through-tubing coiled tubing; conventional with removal of string in open sea; conventional with BOP; superconventional with intermediate/lower completion removal; superconventional recementing; superconventional PWC; superconventional cutting and recovery of casing and superconventional Section Milling. The list with the hierarchy of abandonment alternatives is then presented, from the most suitable to the least suitable one for the case under analysis.

### BRIEF DESCRIPTION OF THE FIGURES

In order to obtain a complete and total view of the object of this disclosure, the figures to which references are made below are presented.

FIG. 1 illustrates the distribution of the annular spaces used by the tool for wells with or without production liner according to an embodiment of the present disclosure.

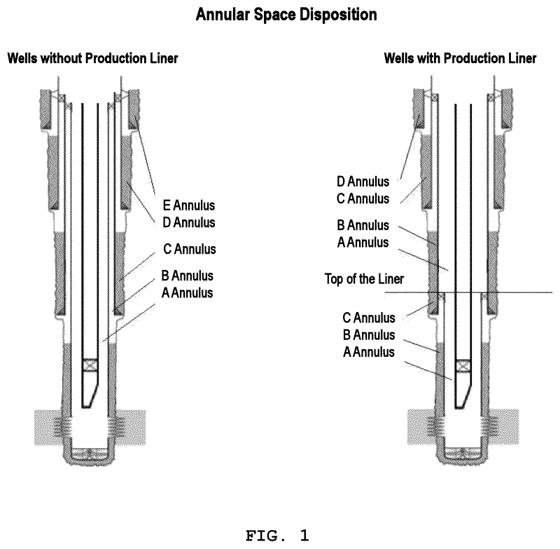

FIG. 2 illustrates the hierarchy used by the tool for the final selection of the eligible alternatives, further considering possible combinations between them according to an embodiment of the present disclosure.

FIG. 3 illustrates a component diagram with elements of the web application, with the data controller acting as an interface between the business rules of the computational tool and the Django application, according to an embodiment of the present disclosure.

FIG. 4 illustrates a flowchart for the user interface according to an embodiment of the present disclosure.

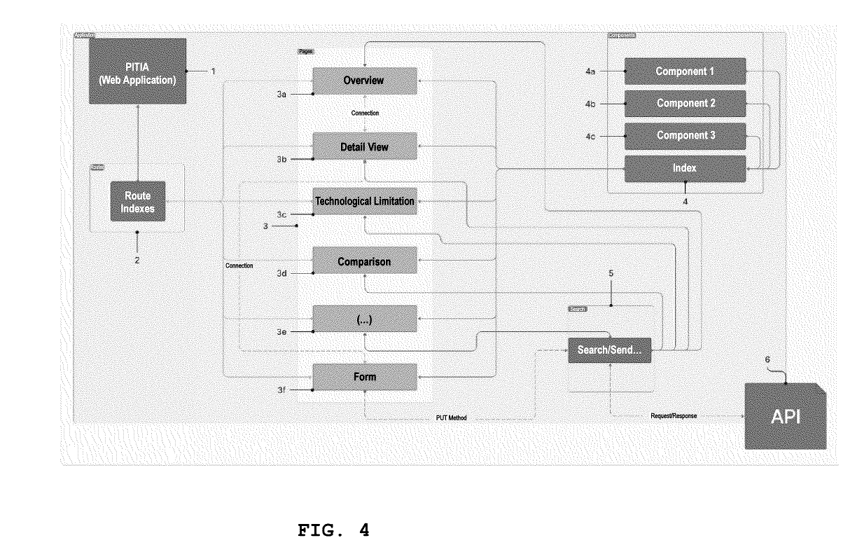

FIG. 5 illustrates a flowchart of the logic of the computational tool for selecting alternatives. It further illustrates the abandonment alternative evaluation algorithm in a more expanded form, according to an embodiment of the present disclosure.

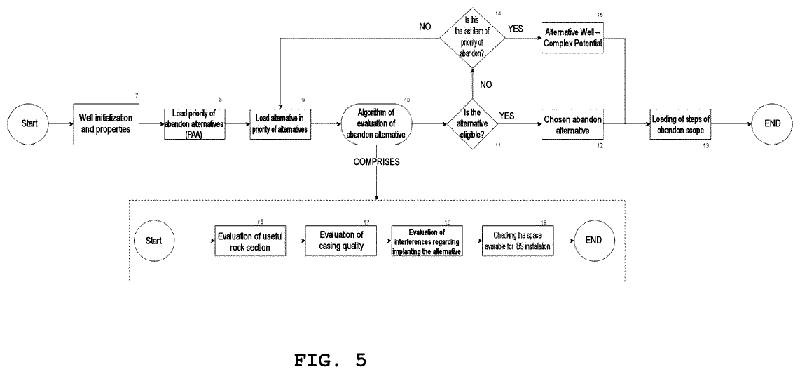

FIG. 6 illustrates the abandonment alternative evaluation algorithm for the DCP—(Direct Cement Pumping) scope, according to another embodiment of the present disclosure.

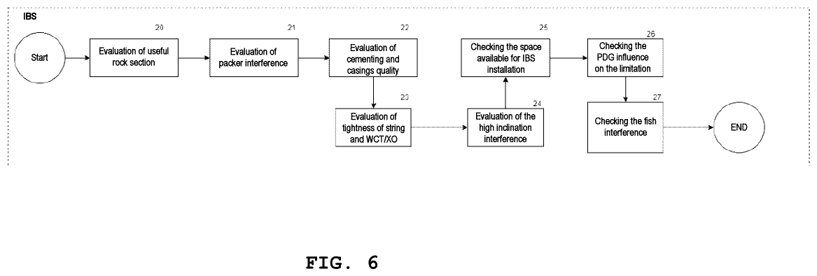

FIG. 7 illustrates the abandonment alternative evaluation algorithm for the CT—(Coiled Tubing Plugging) scope, according to another embodiment of the present disclosure.

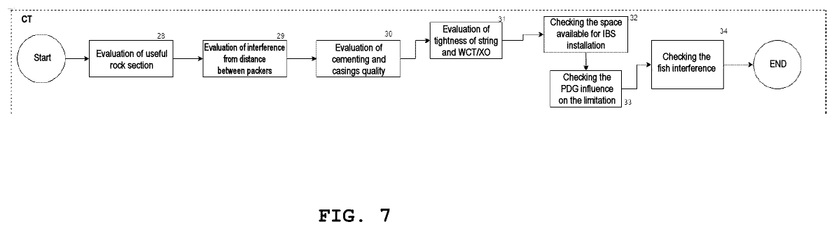

FIG. 8 illustrates the abandonment alternative evaluation algorithm for the OSSR—(Open Sea String Removal) scope, according to another embodiment of the present disclosure.

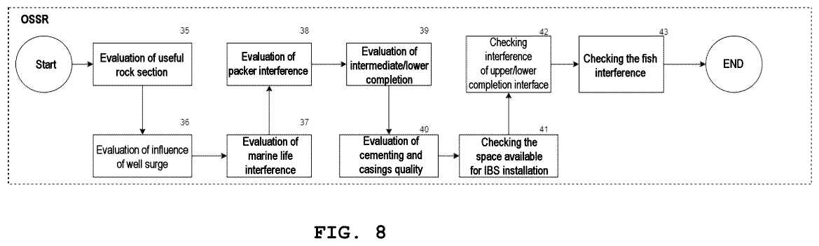

FIG. 9 illustrates the abandonment alternative evaluation algorithm for the BOP (Blow Out Preventer) scope, according to another embodiment of the present disclosure.

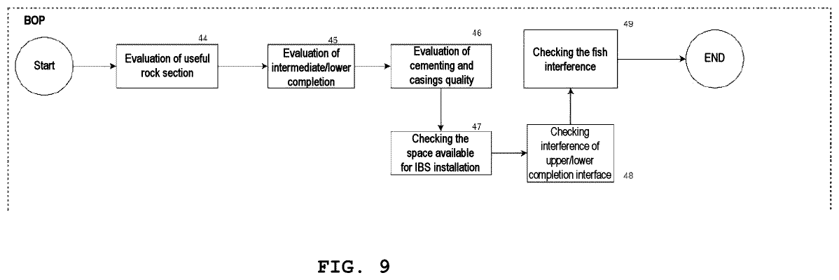

FIG. 10 illustrates the abandonment alternative evaluation algorithm for the Intermediate/Lower Completion Removal scope, according to another embodiment of the present disclosure.

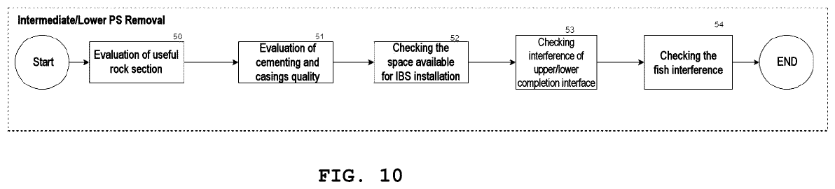

FIG. 11 illustrates the abandonment alternative evaluation algorithm for the Recementation and Cement Correction scope, according to another embodiment of the present disclosure.

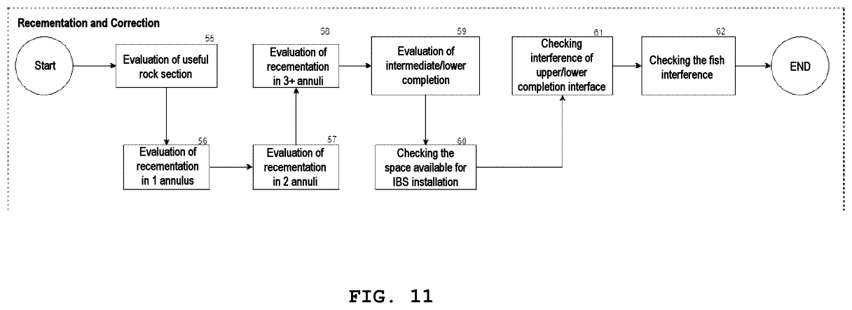

FIG. 12 illustrates the abandonment alternative evaluation algorithm for the PWC—(Perforate, Wash and Cement) scope, according to another embodiment of the present disclosure.

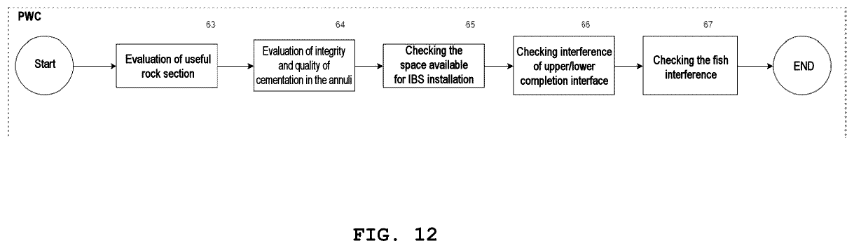

FIG. 13 illustrates the abandonment alternative evaluation algorithm for the Casing Cutting and Recovery scope, according to another embodiment of the present disclosure.

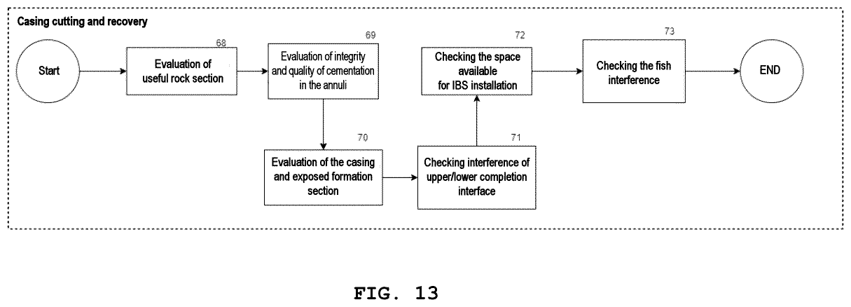

FIG. 14 illustrates the abandonment alternative evaluation algorithm for the Section Milling scope, according another embodiment of the present disclosure.

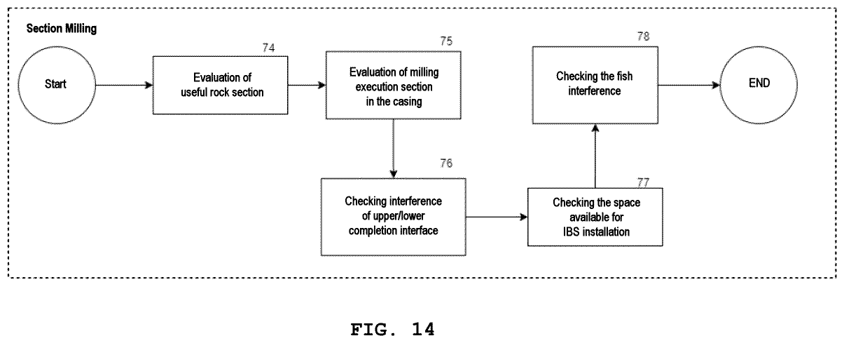

### DETAILED DESCRIPTION OF THE DISCLOSURE

The present disclosure relates to a computer-implemented method and computing device with a modeling of the abandonment process of oil and natural gas wells, being considered a computational tool for intelligent prediction of abandonment of oil and natural gas wells. The method can be integrated with an artificial intelligence that enables a continuous learning cycle.

The method comprises the steps of: collecting information from the databases relating to the well structure and performing a first analysis; wherein the first analysis comprises grouping generic data common to all abandonment alternatives, grouping the scope alternatives into groups; presenting the set of data used and the possible points of attention and alert for each of the scope alternatives; distinguishing, from the groups, the subtypes that will be part of the group of possible selection alternatives; and presenting a list with a hierarchy of the abandonment alternatives, from the most suitable to the least suitable one, wherein the best abandonment alternative in the hierarchy list is presented as the suggested abandonment scope.

The logic used in the computational tool is based mainly on set relations and operations. In general, the tool first loads the data relating to the well structure (e.g. water depth, well depth, casing sizes and expected cement position), loading the other variables according to the needs of each alternative.

Any unstructured data can be included in the database through a form within the tool itself, which considers the most relevant information for analysis and whose access is limited. Changes are blocked for the common user, and are only allowed for special users with editing power in the system.

According to the project definition, the tool analyzes all alternatives considering their peculiarities. If the alternative meets the established criteria, it will be considered possible and will be part of the list of evaluated scopes. Using the established criteria, the eligible alternatives are ranked, and the highest ranked alternative from the list is presented as the suggested abandonment scope.

In order to optimize the computational code, the logical part and the evaluations of the conditions for performing the abandonment common to all alternatives were grouped, keeping only the specific tests under each alternative. The same was done with the groups of alerts and points of attention.

The first evaluations are based on a generic alternative, with features common to all groups and possible alternatives, described below.

### From the Well Builder

The evaluation of the abandonment alternatives available for the wells in the dataset begins with the initialization of the well object, which searches for information about the geometric properties of the well relevant to determine the abandonment alternatives available for the specific case.

At this step, all pertinent information is loaded: well name; field name; basin name; production unit name; intervention dates; water depth; measured depths of the entire well; vertical depths of the entire well; inclinations; position of all casings; position of all cement plugs; position of the sealing rocks; position of the intervals with flow potential; items of the production/injection string (if any), their types and positions; any indications of mechanical/hydraulic access problems to the well, such as fish, damage or problems with the string and WCT—wet Christmas tree tightness; presence of scales; presence of marine life around the well; surge level; competence limits for the sealing rocks; among others.

### From the Generic Alternative

The sealing rock data set is compared with the competence limit, if any. In the initial tests, this limit was established directly (e.g., 500 m above the top of the IFP—Interval with Flow Potential, as a reference).

With access to the databases, the shallowest limits are used to compose the base of the second IBS. From this comparison, the useful sealing rock to be analyzed by the tool is obtained.

In the current phase, the competence calculation is implemented within the tool, taking into account the maximum future pressures of each relevant region, as well as the vertical elevation and cross-referencing with the pressure gradient data of the sealing rock.

### General Well Alerts and Points of Attention

If the well inclination exceeds 62.5°, an alert will be issued informing: “High well inclination from XXXX m to YYYY m”, depending on the inclination range in meters detected for the well in question.

If there are control cables/lines in the completion, a warning will be issued informing that: “The creation of permanent IBS in sections with cables/lines must be previously aligned with the Regulator”.

Position of well items (e.g., GLMs—Gas-Lift Mandrels, DHSV—Down Hole Safety Valve, fish); if there is a sealing rock gap between IFPs with a distance of less than thirty (30) meters, an alert will be issued informing: “There are IFPs with a sealing gap of less than 30 m. Any IBS between zones will have a reduced extension in relation to the agreed upon”.

If there is a section with overlap between casing and production liner and this is not filled with cement, an alert will be issued informing: “It is necessary to position an isolation plug in a section above the top of the liner”.

The type and position of the separation element between the upper and intermediate completions are presented in the form of a point of attention: “Type and position of the interface between upper and lower completions: AAAA, XXXX m” (e.g., TSR—Tubing Seal Receptacle, 2400 m).

For wells with a water depth—WP of <100 m, a warning will be issued: “Pay attention to ANP resolution 817/2020, which addresses with the criteria and requirements for well razing”.

If there is an inclination greater than 62.5° within the selected abandoned section, a warning will be issued: “Inclination greater than 62.5° after a certain number of meters. When installing the IBS, alternative additives and materials must be evaluated to increase the probability of success”.

From the data evaluated in the generic alternative, three (3) larger groups are derived: Through Tubing—TT, Conventional—CN and Superconventional—SN. Each group brings together the tests common to its alternatives, in order to optimize the code, inheriting the necessary information from the generic alternative.

In the same way, the final alternatives for abandonment will subsequently inherit the necessary information from the group to which they belong, including the alerts and points of attention. In the event that no alternative is possible to implement, that is, when the well does not meet any of the requirements of the available alternatives, it is defined as Special Potential, displaying the following alert to the user: “Needs in-depth analysis and study to establish contingency actions”.

### Through Tubing—TT

The definition region for the TT takes into account the geology and equipment present in the well, considering the possibility of abandonment without removing the production/injection string. The useful sections are calculated following the abandonment guidelines.

Further according to the guidelines, the rules for the presence of cables and/or control lines inside the well are considered.

The tool is capable of evaluating the useful regions for this group of alternatives. The data will be presented in the detailed view, in the individual tab for the TT-DCP & CT group. If there is an element with a control cable/line (e.g., PDG), a warning will be issued informing its depth.

If there is no space below the element that allows the selection of TT alternatives, an alert will be issued informing that the same is ineligible. Thus, it will be calculated in the specific tab, with the intervals for consideration, but will not be presented as a suggested scope.

### Alerts and Points of Attention—TT

If there are control cables/lines inside the well in the section selected for TT, a warning will be issued: “The creation of permanent IBS in sections with cables/lines must be previously aligned with the Regulator”.

During the final analysis and ranking of the alternatives, if the PDG cables/lines inside the well make it impossible to install IBSs, an alert will be issued: “Alternative not eligible”.

When the available distance does not allow the approval by Operational Parameters, but allows the operation by other methods, the following warning will be issued: “It is not possible to perform cement verification via Operational Parameters”.

If the verification by operational parameters is possible, the following warning will be issued: “Possibility of verification via Operational Parameters—OP”.

Fish found inside the well are considered to be internal to the PS/IS—Production String/Injection String, and will directly interfere with the TT alternatives.

In this way, whenever there is fish, both possibilities will be analyzed: one for the case in which the fish is recoverable and one for the case in which it is not recoverable. In any case, the following alert will be displayed: “Presence of fish from XXXX m”, according to the number of meters in which the fish was identified.

### Direct Cement Pumping—DCP

The DCP inherits the data evaluated and filtered in its group, the TT. For this alternative, the original structural data of the well are considered, as well as the current condition of the string, since pumping is performed through the same. The data is read and the tool performs the evaluation of the alternative.

In cases where there are impeding elements, which cannot be corrected, the alternative will not be listed among those that can be executed.

### Alerts and Points of Attention—DCP

If the string shows an indication of non-tightness, an alert will be issued: “String with indication of non-tightness. Reevaluate the tightness of the PS/IS”.

### Coiled Tubing—CT

Similarly, the TT CT also inherits the data from the TT (Through Tubing) set, although with small changes in logic, since there is less dependence on the conditions of the string inserted in the well. This means that whenever there is a TT DCP, there is also the possibility of a TT CT.

It was established that the TT CT alternative cannot be applied in the region below the deepest packer. In this way, the entire interval below the deepest packer is considered unavailable for this alternative.

### Alerts and Points of Attention—CT

Whenever there is a possibility of TT CT, the point of attention will be displayed: “Attention to operational limitation of Riserless-type units”.

### Conventional—CN

After using the geological and structural data of the well, the tool performs a filtering of the regions where the conventional type alternatives are applicable.

In general, the data on casings, cement and the positions of the sealing elements and with flow potentials are checked.

In accordance with the industry guidelines and good practices, the alternatives follow the precepts established for correct isolation and consider the limitations imposed by the completion sections originally used in the wells.

### Alerts and Points of Attention—CN

When the available distance does not allow approval by Operational Parameters, but allows the operation by other methods, the following warning will be issued: “It is not possible to perform cement verification via Operational Parameters”.

If the verification by operational parameters is possible, the following warning will be issued: “Possibility of verification via Operational Parameters-OP”.

### Open Sea String Removal—OSSR

The CN OSSR alternative inherits the data from the Conventional group, but considers elements with potential for damage during the abandonment, such as well surge and the presence of marine life around the well.

Since some of these elements are limiting, the alternative, despite presenting an available region with a size greater than the minimum required, may be considered ineligible in cases where the existence and/or criticality are above the limits established in the code.

### Alerts and Points of Attention—OSSR

An alert will be issued in case of presence of marine life around the well: “Presence of marine life within a radius of up to 100 m around the well”.

A point of attention will be displayed informing the position of the upper packer.

For level 1 surging wells, inform: “Level 1 surging well. Assess whether the use of eIBS fluid without solids applies to the scope”.

For wells with a surge level greater than 1, an alert will be issued: “OSSR alternative cannot be implemented due to the surge level being greater than 1”.

### BOP

The CN BOP alternative also inherits information from the Conventional group. However, unlike the CN OSSR, the BOP does not have additional evaluations. The inherited interval is the final interval for this alternative, and is considered possible whenever there is a possible CN OSSR. Likewise, the alerts displayed are also the same as those inherited from its group.

### Superconventional—SN

Given its peculiarities, the Superconventional group uses, for the most part, only the basic structural data of the well. The exception is the SN Intermediate/Lower Completion Removal, which has similar features to the CN group.

General alerts and points of attention for the SN group are the same as those inherited from the generic alternative. Additionally, the wells are evaluated in relation to the possibility of performing the Optimized SN Abandonment, indicated as “shallow”, that is, whether it is necessary to perform an Intermediate/Lower Completion Removal operation. Regarding the removal operation:

If the operation is not necessary, the warning “Possibility of executing alternative only with removal of the upper completion” is displayed.

If necessary, the message “Alternative requires removal/fishing of intermediate/lower completion” will be displayed.

### Intermediate/Lower Completion Removal

This alternative, despite being part of the SN group, has CN features. It performs the same tests as the BOP, but does not have some limitations imposed by the string inserted in the well.

In this way, if the CN BOP alternative, for example, was made impossible only due to completion-related issues, the SN Intermediate/Lower Completion Removal alternative will present possible regions for the composition of the IBSs. Alerts and points of attention are the same inherited from the CN group and the generic alternative.

### Recementation

The recementation inherits data from the SN group. As it is an alternative that allows cement correction in practically any condition, the tool analyzes the recementation for cases in which there is deficient cementation.

Alerts and specific conditions: In cases where there is the possibility of recementing one or more annuli, the alert will be displayed, respectively: “Recementing possible in 1/2/more than 2 annuli”.

For any of the possible cases, the following point of attention will be displayed: “Risk of releasing any gas/oil trapped behind the casing.

### Perforate, Wash and Cement—PWC

After inheriting the data from the SN group, this alternative compares the points where the indicated cement exists. For the SN PWC, the tool will indicate when it is possible to perform it for one or two annuli, depending on the structural conditions of the analyzed well.

### Alerts and Points of Attention—PWC

The following point of attention will be displayed: “Risk of releasing any gas/oil trapped behind the casing”.

The following alert will be displayed: “Attention to the need for additional analyses to manage waste generated during the operation”.

The PWC will be considered “shallow” when there is sufficient space for positioning IBSs above the upper/intermediate completion interface. In other words, when a recovery of the intermediate and/or lower completion is not necessary.

The PWC will be considered “bottom” when this recovery is necessary to provide sufficient space for the establishment of the IBSs.

### Casing Cutting and Recovery

This alternative inherits the useful sealing rock data and compares the regions where there is no cement in the B annulus. There are two important criteria to be met for this alternative:
If the uncemented B annulus is in a region of exposed formation, the available cutting section will be limited to up to 30 meters within the uncemented exposed formation;
For cases in which the uncemented B annulus is in a section with concentric casings, it is mandatory that the cutting point occurs in a region with good cementation of the C annulus.

The SN Casing cutting and recovery alternative has a different feature given its nature: the shallowest possible cutting region within the indicated section already includes a minimum combined IBS of 60 meters. In other words, if the cut is made at the shallowest point indicated, there will only be space for the composition of a combined IBS of 60 meters.

Only a piece or “window” cannot be removed; all the casing above the cut must be removed from the well.

### Alerts and Points of Attention—Casing Cutting and Recovery

The following point of attention will be displayed: “Risk of releasing any gas/oil trapped behind the casing”.

If available, the following alert will be displayed: “Attention to the need to consider the minimum section for the composition of IBS”.

### Section Milling

The last alternative analyzed within the SN group inherits the useful sealing rock data and compares it with the sections where there is cement indicated in B annulus. The section to be destroyed must be at least thirty (30) meters long, in order to accommodate at least one (1) IBS.

### Alerts and Points of Attention—Section Milling

The following point of attention will be displayed: “Risk of releasing any gas/oil trapped behind the casing.

### Alternative Selection

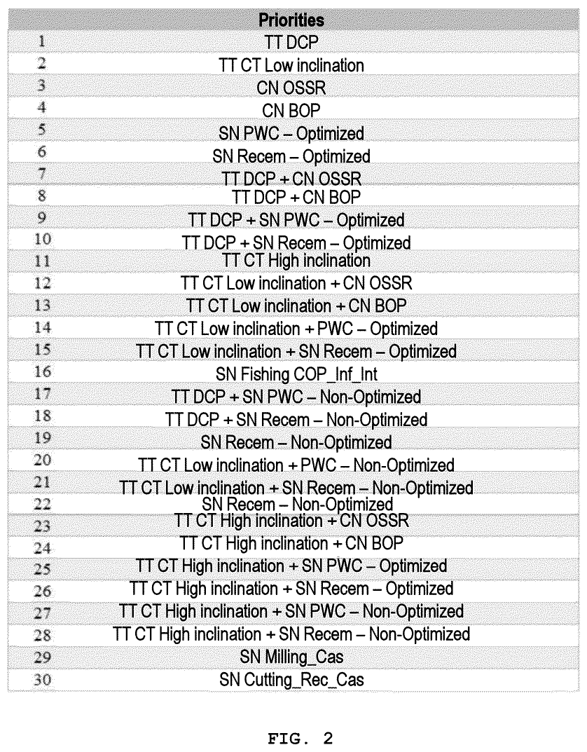

As shown in FIG. 2, after analyzing all possible routes, the chosen alternative will be the one that is eligible, follows the order below and is best classified.

### Code Development

The development of the tool follows the precepts of the 12 factors for designing web applications and other development modern guidelines, with the development of web applications primarily in containers (Web First and Container First) being recommended.

The application was developed for the Web platform using Python language and the Django and Django-REST frameworks for the backend. The backend communicates with the web interface via RPC/HTTP requests (GET, POST and PUT methods) and responses in JSON format, commonly used in communications with REST APIs. The frontend was developed using JavaScript/TypeScript with the React framework.

After defining the basic structure of the business rules for the tool, following the principles of decoupling between components and code dependency inversion, the web system was designed to have minimal dependencies and coupling between the Django models and tools and the components of the computational tool, to improve the development and maintenance of both.

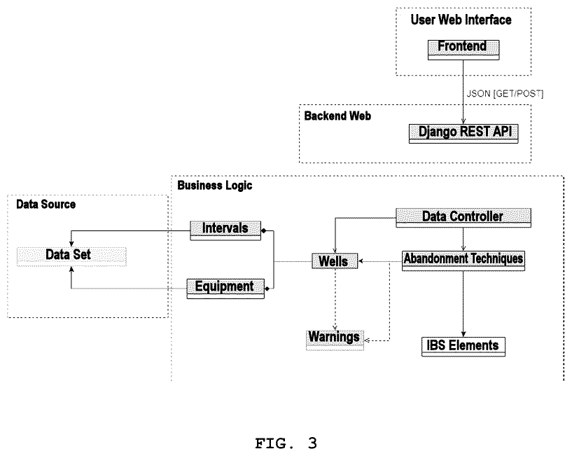

With this scenario in mind, the tool was installed as an application separate from the Django application, and a new component for data control was developed so that Django could interact with the same. Thus, the component diagram of the tool in the Web version is shown in FIG. 3.

As can be seen in FIG. 3, the Data Controller component acts as a communication interface between the PiTiA business rules and the Django application, promoting decoupling between the components.

Following the implementation process, the Development, Approval and Production environments were made available for deploying the application, which allows testing of new functionalities without impacting the website in the event of a problem. The application was encapsulated in containers to allow the CI/CD flow using the Jenkins and Kubernetes platforms.

Those skilled in the art will value the knowledge presented herein and will be able to reproduce the disclosure in the presented embodiments and in other variants encompassed by the scope of the attached claims.

1. A computer-implemented method with a modeling of the abandonment process of oil and natural gas wells, the method comprising:
collecting information from the databases relating to the structure of the well and performing a first analysis, the first analysis comprises grouping generic data common to all abandonment alternatives,
grouping the scope alternatives into groups;
presenting the set of data used and the possible points of attention and alerts for each of the scope alternatives;
distinguishing, from the groups, the subtypes that will be part of the group of possible selection alternatives; and
presenting a list with a hierarchy of the abandonment alternatives, from the most suitable to the least suitable one, the best abandonment alternative in the hierarchy list is presented as the suggested abandonment scope.

2. The method according to claim 1, wherein an individual analysis is performed for each well in the database.

3. The method according to claim 1, wherein the wells are in any phase of their respective productive lives.

4. The method according to claim 1, wherein the method is integrated with an artificial intelligence that enables a continuous learning cycle.

5. The method according to claim 1, wherein the groups are Through-Tubing, Conventional and Superconventional.

6. The method according to claim 1, wherein the subtypes are through-tubing with direct pumping of cement, through-tubing coiled tubing, conventional with open sea string removal, conventional with BOP; superconventional with intermediate/lower completion removal, superconventional recementing, superconventional PWC, superconventional casing cutting and recovery, and superconventional Section Milling.

7. The method according to claim 1, wherein the used logic is based on the relations and operations of sets.

8. The method according to claim 1, wherein the data relating to the well structure are preferably the name of the well, name of the field, name of the basin, name of the production unit, intervention dates, water depth, measured depths of the entire well, vertical depths of the entire well, inclinations, position of all casings, position of all cement plugs, position of the sealing rocks, position of the intervals with flow potential, items of the production/injection string, their types and positions, any indications of problems with mechanical/hydraulic access to the well such as fish, damage or problems with the tightness of the string and the WCT-wet Christmas tree, presence of scales, presence of marine life around the well, surge level and limits of competence for the sealing rocks.

9. The method according to claim 1, wherein data relating to the structure of the unstructured well are optionally included in the database, via a form.

10. The method according to claim 1, further comprising if no well abandonment alternative is possible to implement or when the well does not meet any of the requirements of the available alternatives, it is defined as Special Potential.
